(19) United States
(12) Patent Application Publication
(10) Pub. No.: US 2024/0343553 A1
(43) Pub. Date: Oct. 17, 2024

(54) SEMICONDUCTOR PACKAGE WITH FLOATING METAL PORTION AND METHOD FOR MANUFACTURING

(71) Applicant: Infineon Technologies AG, Neubiberg (DE)

(72) Inventors: Horst THEUSS, Wenzenbach (DE); Chau Fatt CHIANG, Taman Bertam Setia (MY); Chee Hong LEE, Taman Paya Rumput Utama (MY); Rainer Markus SCHALLER, Aichen (DE); Kok Yau CHUA, Taman Semabok (MY); Julianous KETIHUS, Melaka (MY); Khay Chwan ANDREW SAW, Taman Gangsa Impian (MY)

(21) Appl. No.: 18/626,029

(22) Filed: Apr. 3, 2024

(30) Foreign Application Priority Data
Apr. 14, 2023 (DE) 102023109409.2

(51) Int. Cl. B81B 3/00; B81C 1/00; H01L 23/31

(52) U.S. Cl. CPC B81B 3/0021; B81C 1/00492; H01L 23/3107

(57) ABSTRACT

Examples disclose a semiconductor package including a semiconductor chip, an encapsulation, and a metal structure. The semiconductor chip is at least partially embedded in the encapsulation. The metal structure is formed on an outer surface of the encapsulation and includes a floating portion. The floating portion is floating on the encapsulation and the metal structure is electrically coupled with the semiconductor chip. Further examples disclose a method for manufacturing a semiconductor package, the method including providing a semiconductor chip at least partially embedded in an encapsulation; providing a metal structure on the encapsulation; forming a floating portion of the metal structure by forming a recess in the encapsulation.

### CROSS-REFERENCE TO RELATED APPLICATION

This application claims priority to German Patent Application No. 102023109409.2 filed on Apr. 14, 2023, the content of which is incorporated by reference herein in its entirety.

### TECHNICAL FIELD

Aspects of the present disclosure generally relate to semiconductors.

### BACKGROUND

Many applications require a metallic structure being only surrounded by a fluid and/or being able to move mechanically with respect to a stationary element.

US 2015/084139 A1 discloses techniques and mechanisms for providing precisely fabricated structures of a semiconductor package. In an implementation, a build-up carrier of the semiconductor package includes a layer of porous dielectric material. Seed copper and plated copper is disposed on the layer of porous dielectric material. Subsequent etching is performed to remove copper adjacent to the layer of porous dielectric material, forming a gap separating a suspended portion of a MEMS structure from the layer of porous dielectric material. In another implementation, the semiconductor package includes a copper structure disposed between portions of an insulating layer or portions of a layer of silicon nitride material. The layer of silicon nitride material couples the insulating layer to another insulating layer. One or both of the insulating layers are each protected from desmear processing with a respective release layer structure.

However, the techniques disclosed in US 2015/084139 A1 are not suitable for back-end of line (BEOL) processing.

### SUMMARY

There may be a need for a semiconductor package with a floating metal portion and a method for manufacturing the package being suitable for BEOL processing.

The need has been addressed with the subject-atter of the independent claims. The dependent claims describe advantageous implementations.

Examples disclose a semiconductor package including a semiconductor chip, an encapsulation, wherein the semiconductor chip is at least partially embedded in the encapsulation, a metal structure formed on an outer surface of the encapsulation, wherein the metal structure includes a floating portion, wherein the floating portion is floating on the encapsulation, wherein the metal structure is electrically coupled with the semiconductor chip.

Further examples disclose a method for manufacturing a semiconductor package, the method including providing a semiconductor chip at least partially embedded in an encapsulation; providing a metal structure on the encapsulation; forming a floating portion of the metal structure by forming a recess in the encapsulation.

### BRIEF DESCRIPTION OF THE DRAWINGS

Implementations will now be explained with reference to the enclosed figures.

FIG. 1 shows a semiconductor package in a perspective view;

FIG. 2 shows the semiconductor package of FIG. 1 in a plan view;

FIG. 3 shows the semiconductor package of FIG. 1 in a cross-sectional view;

FIG. 4 shows a semiconductor package in a perspective view;

FIG. 5 shows the semiconductor package of FIG. 4 in a plan view;

FIG. 6 shows the semiconductor package of FIG. 4 in a cross-sectional view;

FIG. 7 shows a semiconductor package in a perspective view;

FIG. 8 shows the semiconductor package of FIG. 7 in a plan view;

FIG. 9 shows the semiconductor package of FIG. 7 in a cross-sectional view;

FIG. 10 shows a semiconductor package in a perspective view;

FIG. 11 shows the semiconductor package of FIG. 10 in a plan view;

FIG. 12 shows the semiconductor package of FIG. 10 in a cross-sectional view;

FIG. 13 shows a semiconductor package in a plan view;

FIG. 14 shows the semiconductor package of FIG. 13 in a cross-sectional view;

FIG. 15 shows a semiconductor package in a plan view;

FIG. 16 shows the semiconductor package of FIG. 10 in a cross-sectional view;

FIG. 17 shows a semiconductor package in a cross-sectional view;

FIG. 18 shows a semiconductor package in a cross-sectional view; and

FIG. 19 shows a semiconductor package in a cross-sectional view.

### DETAILED DESCRIPTION

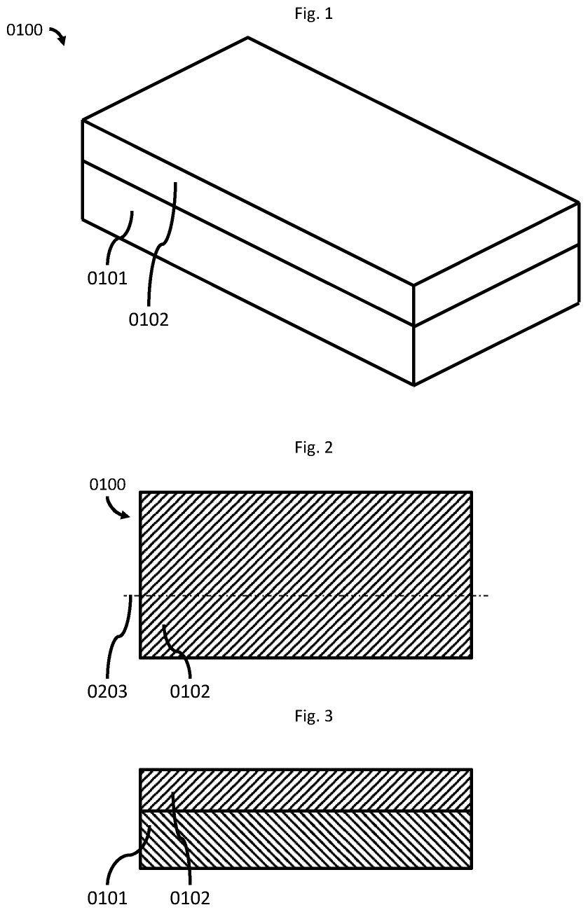

FIGS. 1 to 3 show a semiconductor package 0100 comprising an encapsulation 0101, 0102, wherein a semiconductor chip (not shown) is at least partially embedded in the encapsulation 0101, 0102. FIG. 1 shows a perspective view of the semiconductor package 0100, FIG. 2 a plane view of the semiconductor package 0100 and FIG. 3 a cross-sectional view of the semiconductor package 0100 along the section line 0203 depicted in FIG. 2.

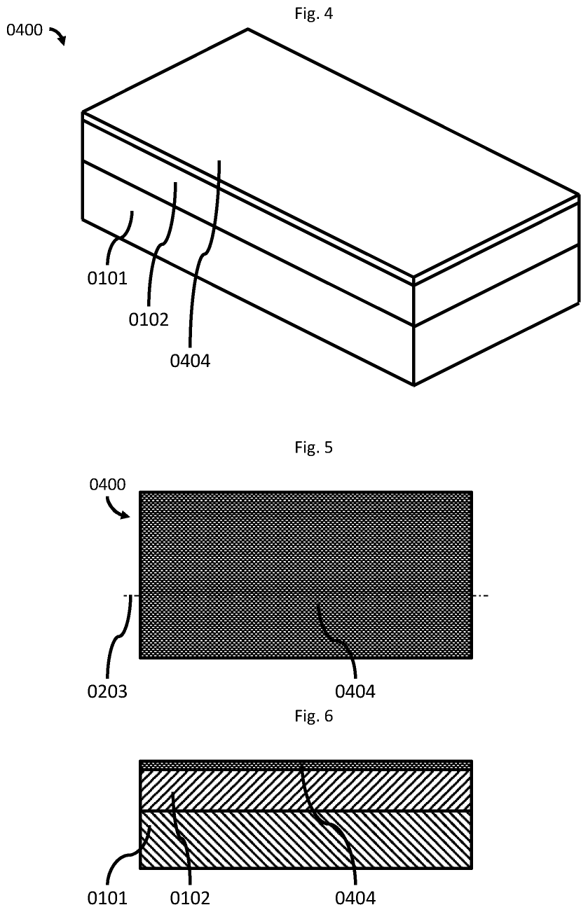

FIGS. 4 to 6 show a semiconductor package 0400 obtained after a processing step after plating a surface of the encapsulation 0102 with a first metal 0404 the obtained metal layer 0404 may be formed. The first metal forming the metal layer 0404 may comprise at least one of copper (Cu), aluminum (Al), tungsten (W), nickel (Ni), palladium (Pd), and platinum (Pt).

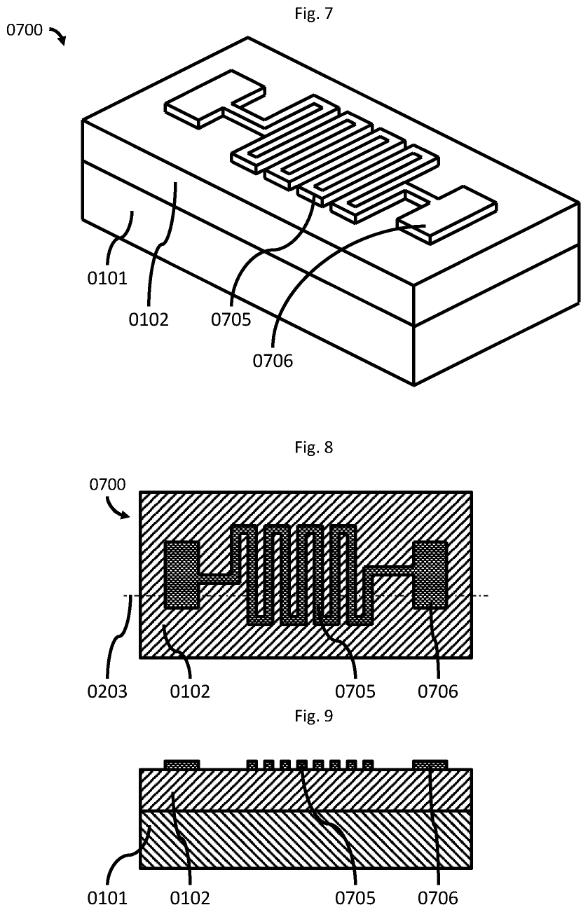

FIGS. 7 to 9 show a metal structure 0705, 0706 on the encapsulation 0102. The metal structure 0705, 0706 may have been formed by structuring the metal layer 0404. However, the metal structure 0705, 0706 may also have been formed directly on the surface of the encapsulation 0102, e.g., by printing a first metal structure on the surface of the encapsulation 0102.

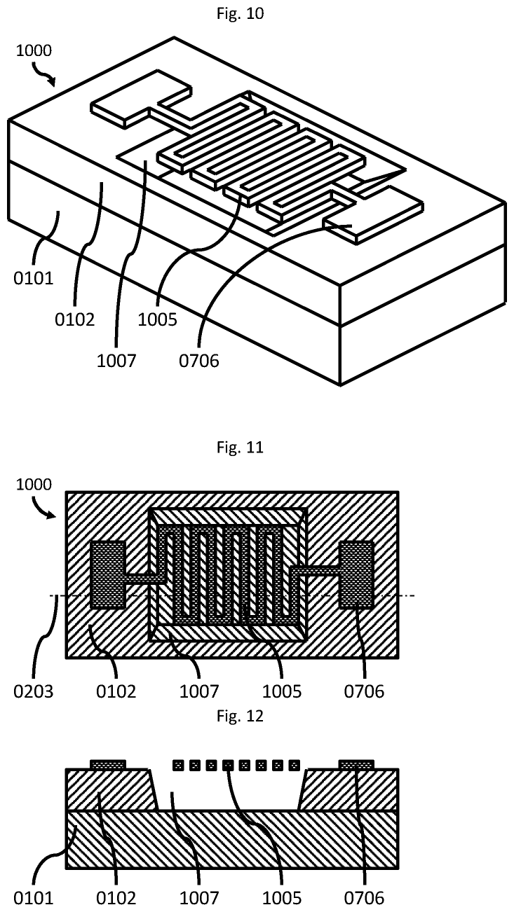

As shown in FIGS. 10 to 12, a recess 01007 may be formed in the encapsulation 0101. The formation of the recess 01007 results in forming a floating portion 1005 of the metal structure 0705, 0706. Forming the recess 1007 in the encapsulation 0102 may comprise removing a portion of the encapsulation 0102 using a laser. In addition or as an alternative, forming the recess 0102 in the encapsulation 1007 in the encapsulation 0102 may comprise etching a portion of the encapsulation 0120. In particular, the laser processing may be used for window opening and a chemical removal may be used for cleanup/enabling the metal to be free from the encapsulation.

The recess 1007 may have a rectangular, in particular square, or round, in particular circular or elliptical, opening. In some examples, the metal structure 1005, 0706, in particular the floating portion 0706 may comprise at least one of a meander 0706 and a pad 0706. In further examples, the metal structure may also comprise at least one of a coil or a trace.

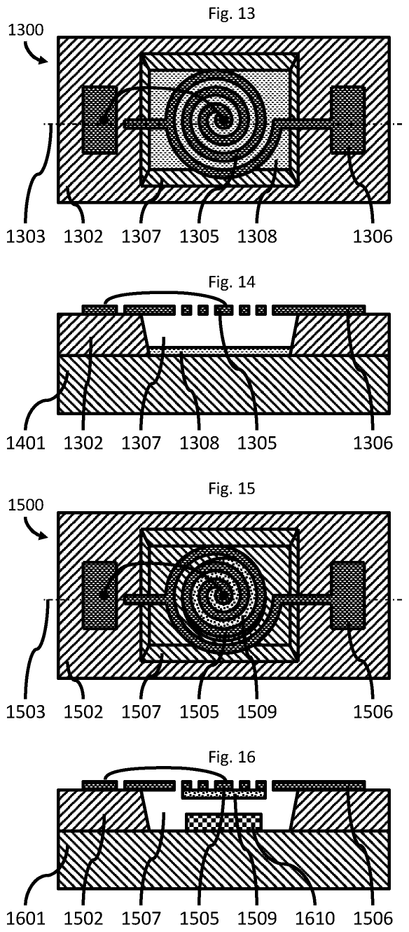

FIGS. 13 and 14 show a further semiconductor package 1300 comprising an encapsulation 1401, 1302, a recess 1307, a floating portion 1305 and a metal structure 1306.

FIG. 14 is a cross-sectional view of the semiconductor package 1300 shown in plane view along the section line 1303 shown in FIG. 13. While the processing steps to obtain the floating portion 1305 may be similar to the processing explained with respect to FIGS. 1 to 12, the floating portion 1305 comprises a coil. Moreover, the recess 1307 is at least partially covered with a second metal 1308, wherein a second metal 1308 may be different from or the same as the first metal forming the floating portion 1305 and the metal structure 1306.

In particular, the second metal 1308 may comprise at least one of copper (Cu), aluminum (Al), tungsten (W), nickel (Ni), palladium (Pd), and platinum (Pt).

The second metal 1308 may be provided only at the bottom of the cavity 1307 as shown in FIGS. 13 and 14. However, in addition or as an alternative, the second metal may also be provided at a side wall of the cavity 1307. The floating portion 1305 and the second metal 1308 may form an antenna. In particular, the second metal 1308 may be considered a ground plate for the antenna.

FIGS. 15 and 16 show a further semiconductor package 1500 in plane view (FIG. 15) and in a cross-sectional view (FIG. 16) along the sectional line 1503.

The semiconductor package 1500 comprises an encapsulation 1601, 1502 at least partially encapsulating a semiconductor chip (not shown). A metal structure 1505, 1506 comprising a floating portion 1505 floating on the encapsulation 16601 is formed by removing a portion of the encapsulation 1502. The semiconductor package 1500 further comprises a diaphragm 1509 and a magnet 1610. Hence, the metal structure 1505 may be part of a speaker.

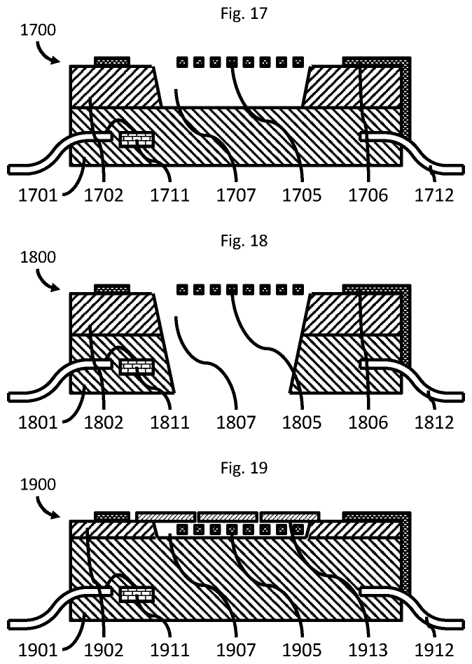

FIGS. 17 to 19 show further semiconductor packages 1700, 1800, 1900. The semiconductor packages 1700, 1800 and 1900 comprise a lead frame 1712, 1812, 1912 and semiconductor chips 1711, 1811, 1911 connected to the respective lead frame.

The semiconductor chips 1711, 1811, 1911 are at least partially embedded in encapsulations 1701, 1702, 1801, 1802, 1902. Floating portions 1705, 1805, 1905 of metal structures 1705, 1706; 1805, 1806; 1905 are floating above the encapsulations 1701, 1801, 1901.

The encapsulation 1701, 1702; 1801, 1802; 1901, 1902 may comprise a substrate 1701, 1801, 1901. The substrate may be made of at least one of plastic, glass, ceramics, metal, PCB-like material. The encapsulation 1702, 1802, 1902 may cover the substrate 1701, 1801, 1901 and may comprise a resist. The resist may be removed to form the floating portions 1705, 1805, 1905. The process may be realized in form of a modified and fan-out wafer level package flow.

As shown in FIG. 17, the metal structure may be the metal structure 1706 may be electrically connected to the lead frame 1712.

The material below the floating portion 185 may be completely removed to obtain a recess 1807 in form of a through hole.

As shown in FIG. 19, the floating portion may be provided in an indention of the encapsulation 1901, 1902. This may allow for a planner placement of a lid 1913.

The semiconductor packages disclosed herein, in particular those shown in FIGS. 1 to 19, may allow for integrating the floating portions with other components (semiconductor, passive components, etc.).

### ASPECTS

Some implementations are defined by the following ASPECTS:

Aspect 1. A semiconductor package comprising a semiconductor chip, an encapsulation, wherein the semiconductor chip is at least partially embedded in the encapsulation, a metal structure formed on an outer surface of the encapsulation, wherein the metal structure comprises a floating portion, wherein the floating portion is floating on the encapsulation, wherein the metal structure is electrically coupled with the semiconductor chip.

Aspect 2. The semiconductor package of aspect 1, wherein the metal structure, in particular the floating portion, comprises at least one of a meander, a coil, a trace, and a pad.

Aspect 3. The semiconductor package of aspect 1 or 2, wherein the metal structure is made of a first metal, wherein the first metal comprises at least one of copper, Cu, aluminum, Al, Tungsten, W, nickel, Ni, palladium, Pd, platinum, Pt.

Aspect 4. The semiconductor package of any one of aspects 1 to 3, wherein the encapsulation comprises a recess, wherein the floating portion is provided above the recess.

Aspect 5. The semiconductor package of aspect 4, wherein the recess is at least partially covered with a second metal, wherein the second metal is different from or the same as the first metal.

Aspect 6. The semiconductor package of aspect 5, wherein the second metal comprises at least one of copper, Cu, aluminum, Al, Tungsten, W, nickel, Ni, palladium, Pd, platinum, Pt.

Aspect 7. The semiconductor package of any one of aspects 1 to 6, wherein the metal structure is part of at least one of a heater, antenna, speaker, a switch, a resistor, in particular a gas sensor element.

Aspect 8. The semiconductor package of any one of aspects 1 to 7, wherein the metal structure is covered with a lid.

Aspect 9. The semiconductor package of any one of aspects 1 to 8, wherein the floating portion is provided in an indention of the encapsulation.

Aspect 10. The semiconductor package of any one of aspects 4 to 9, wherein the recess has a rectangular, in particular square, or round, in particular circular or elliptical, opening.

Aspect 11. A method for manufacturing a semiconductor package, in particular a semiconductor package according to any one of aspects 1 to 10, the method comprising providing a semiconductor chip at least partially embedded in an encapsulation; providing a metal structure on the encapsulation; forming a floating portion of the metal structure by forming a recess in the encapsulation.

Aspect 12. The method for aspect 11, wherein providing the metal structure on the encapsulation comprises at least one of plating a surface of the encapsulation with a first metal, or printing a first metal on a surface of the encapsulation.

Aspect 13. The method of aspect 12, wherein providing the metal structure on the encapsulation comprises structuring the first metal.

Aspect 14. The method of any one of aspects 1 to 13, wherein forming a recess in the encapsulation comprises removing a portion of the encapsulation using a laser.

Aspect 15. The method of any one of aspects 1 to 14, wherein forming a recess in the encapsulation comprises etching a portion of the encapsulation.

Although specific implementations have been illustrated and described herein, it will be appreciated by those of ordinary skill in the art that a variety of alternate and/or equivalent implementations may be substituted for the specific implementations shown and described without departing from the scope of the present implementation. This application is intended to cover any adaptations or variations of the specific implementations discussed herein. Therefore, it is intended that this implementation be limited only by the claims and the equivalents thereof.

1. A semiconductor package comprising:
a semiconductor chip;
an encapsulation, wherein the semiconductor chip is at least partially embedded in the encapsulation; and
a metal structure formed on an outer surface of the encapsulation,
wherein the metal structure comprises a floating portion,
wherein the floating portion is floating on the encapsulation, and
wherein the metal structure is electrically coupled with the semiconductor chip.

2. The semiconductor package of claim 1, wherein the floating portion comprises at least one of a meander, a coil, a trace, or a pad.

3. The semiconductor package of claim 1, wherein the metal structure is made of a first metal, and
wherein the first metal comprises at least one of a copper, an aluminum, a Tungsten, a nickel, a palladium, or a platinum.

4. The semiconductor package of claim 3, wherein the encapsulation comprises a recess, and
wherein the floating portion is provided above the recess.

5. The semiconductor package of claim 4, wherein the recess is at least partially covered with a second metal, and
wherein the second metal is different from the first metal.

6. The semiconductor package of claim 5, wherein the second metal comprises at least one of a copper, an aluminum, a Tungsten, a nickel, a palladium, or a platinum.

7. The semiconductor package of claim 1, wherein the metal structure is part of at least one of a heater, an antenna, a speaker, a switch, a resistor, or a gas sensor element.

8. The semiconductor package of claim 1, wherein the metal structure is covered with a lid.

9. The semiconductor package of claim 1, wherein the floating portion is provided in an indention of the encapsulation.

10. The semiconductor package of claim 4, wherein the recess has a rectangular opening, a circular opening, or an elliptical opening.

11. A method for manufacturing a semiconductor package, the method comprising:
providing a semiconductor chip at least partially embedded in an encapsulation;
providing a metal structure on the encapsulation; and
forming a floating portion of the metal structure by forming a recess in the encapsulation.

12. The method for claim 11, wherein providing the metal structure on the encapsulation comprises at least one of:
plating a surface of the encapsulation with a first metal or
printing a first metal on the surface of the encapsulation.

13. The method of claim 12, wherein providing the metal structure on the encapsulation comprises:
structuring the first metal.

14. The method of claim 11, wherein forming the recess in the encapsulation comprises:
removing a portion of the encapsulation using a laser.

15. The method of claim 11, wherein forming the recess in the encapsulation comprises:
etching a portion of the encapsulation.

16. A device comprising:
a semiconductor package, wherein the semiconductor package comprises:
an encapsulation;
a semiconductor chip at least partially embedded in the encapsulation; and
a metal structure that is electrically coupled with the semiconductor chip,
wherein at least a portion of the metal structure is floating on the encapsulation.

17. The device of claim 16, wherein the at least a portion of the metal structure comprises one or more of a meander, a coil, a trace, or a pad.

18. The device of claim 16, wherein the at least a portion of the metal structure is floating above a recess formed in the encapsulation.

19. The device of claim 18, wherein the metal structure comprises a first metal and a second metal, that is different from the first metal, at least partially covers the recess.

20. The device of claim 18, wherein the metal structure comprises a first metal and a second metal at least partially covers the recess,
wherein the first metal and the second metal comprise a same metal.
